(19) United States
(12) Patent Application Publication
(10) Pub. No.: US 2008/0044998 A1
(43) Pub. Date: Feb. 21, 2008

(54) Method of Fabricating Metal Interconnection of Semiconductor Device

(76) Inventor: DONG YEAL KEUM, Icheon-si (KR)

Correspondence Address: SALIWANCHIK LLOYD & SALIWANCHIK;A PROFESSIONAL ASSOCIATION, PO BOX 142950, GAINESVILLE, FL, 32614-2950, US

(21) Appl. No.: 11/839,171

(22) Filed: Aug. 15, 2007

(30) Foreign Application Priority Data
Aug. 18, 2006 (KR) 10-2006-0078288

(51) Int. Cl. H01L 21/4763

(52) U.S. Cl. 438/618; 257/E21.495

(57) ABSTRACT

A method of fabricating a metal interconnection of a semiconductor device is provided. According to an embodiment, spacers are formed at sidewalls of a first via hole in a first interlayer dielectric layer. Then, a second interlayer dielectric layer is deposited on the via hole having the spacers. A second via hole and trench are formed through the second interlayer dielectric layer and remaining first interlayer dielectric layer below the first via hole to expose a lower layer. Metal can be filled in the trench and second via hole to form a metal interconnection. Accordingly, the spacer can improve the cohesive property of the second interlayer dielectric layer, so voids can be inhibited from forming in the second interlayer dielectric layer.

### CROSS-REFERENCE TO RELATED APPLICATION

The present application claims the benefit under 35 U.S.C. §119 of Korean Patent Application No. 10-2006-0078288, filed Aug. 18, 2006, which is hereby incorporated by reference in its entirety.

### BACKGROUND

As semiconductor devices have become highly-integrated and are being operated at a high speed, metal interconnections formed in the semiconductor device are getting micro-sized and multi-layered. As the width of the interconnection becomes reduced, a signal delay may occur due to resistance and capacitance of the metal interconnection. Thus, in order to reduce the signal delay, copper, which is a low-resistance metal, is used as a material for the metal interconnection.

Copper is rarely etched as compared with other metals. Thus, in order to make a copper interconnection, a damascene process is performed. According to the damascene process, a via and a trench are first formed, and then a copper layer is formed to fill the trench. In this state, chemical mechanical polishing is performed relative to the copper layer, thereby forming the metal interconnection.

Since a via has a depth larger than its width, the via may not be completely filled with an insulating layer for forming a trench therein deposited over the via. Therefore, voids may be formed in this insulating layer.

However, a portion of the insulating layer having the void is exposed prior to a portion of the insulating layer without the void. Accordingly, while the portion without the void is being etched, an exposed bottom layer can be overetched and damaged.

### BRIEF SUMMARY

Embodiments of the present invention provide a semiconductor device including an insulating layer without an undesired void formed therein, thereby inhibiting a bottom layer from being overetched.

A method of fabricating a metal interconnection of a semiconductor device according to an embodiment includes forming a diffusion barrier, a first interlayer dielectric layer and an etch stop layer on a substrate; forming a first via by removing some portions of the etch stop layer and the first interlayer dielectric layer through a selective etching process; forming a spacer along sidewalls of the first via; forming a second interlayer dielectric layer filling the first via including the spacer; forming a second via exposing the diffusion barrier through the first via and a trench exposing the second via and the etch stop layer by removing the second interlayer dielectric layer and the first interlayer dielectric layer through a selective etching process; and removing the exposed etch stop layer and diffusion barrier.

### BRIEF DESCRIPTION OF THE DRAWINGS

FIG. 1 is a cross-sectional view showing a metal interconnection of a semiconductor device according to an embodiment of the present invention; and

FIGS. 2 through 5 are cross-sectional views sequentially showing a procedure for fabricating a metal interconnection of a semiconductor device according to an embodiment of the present invention.

### DETAILED DESCRIPTION

Hereinafter, a method of fabricating a metal interconnection of a semiconductor device according to embodiments of the present invention will be described in detail with reference to the accompanying drawings.

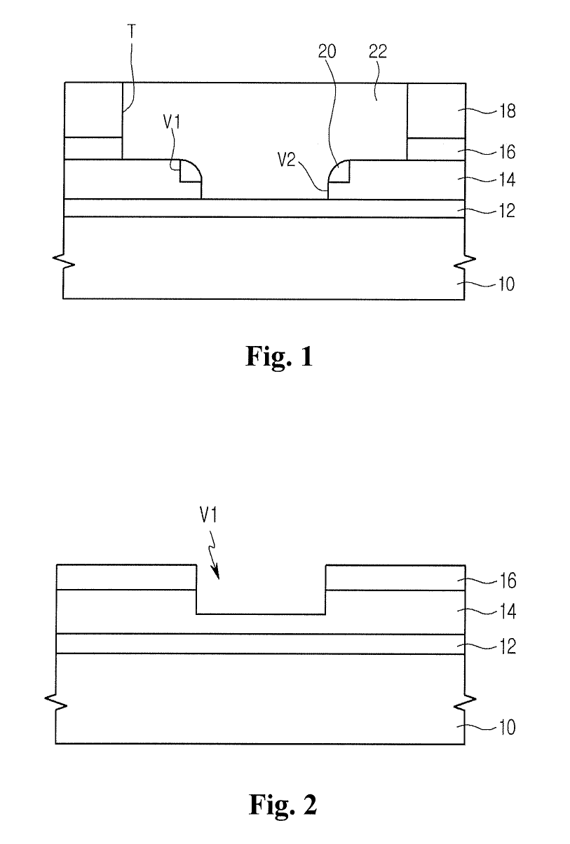

FIG. 1 is a cross-sectional view showing a metal interconnection of a semiconductor device according to an embodiment.

As shown in FIG. 1, a diffusion barrier 12, a first interlayer dielectric layer 14, an etch stop layer 16 and a second interlayer dielectric layer 18 are provided on a substrate 10.

The substrate 10 can include individual elements (not shown) and a lower conductor (not shown). The individual elements may be a transistor, a capacitor and the like, and the lower conductor may be, for example, an interconnection including copper.

The diffusion barrier 12 and the etch stop layer 16 can include a nitride layer (SiN). The first and second interlayer dielectric layers 14 and 18 can be prepared in the form of a single layer or a multi-layer through depositing inorganic insulating materials or organic insulating materials, such as FSG (fluorine silicate glass), USG (un-doped silicate glass), SiH4, or TEOS (tetra ethyl ortho silicate). In addition, the first and second interlayer dielectric layers 14 and 18 can be formed using material having a low dielectric constant, such as BD (BLACK DIAMOND), silica xerogels, mesoporous silica, polyimide nanofoams, TEFLON-AF, or TEFLON microemulsion having a dielectric constant of 3.0 or less.

A first via V1 is can be provided through the second interlayer dielectric layer 18, the etch stop layer 16, and a portion of the first interlayer dielectric layer 14. A spacer 20 having a smoothly curved structure can be formed at a lower corner portion of the first via V1.

In addition, a trench T can be formed through the second interlayer dielectric layer 18 and the etch stop layer 16 in order to expose the spacers 20 of the first via V1 and a second via V2.

The second via V2 and the trench T can be filled with a low-resistance metal, such as copper, in order to form a metal interconnection 22.

Hereinafter, a method of fabricating a metal interconnection of a semiconductor device according to an embodiment having the above structure will be described with reference to FIGS. 2 through 4.

FIGS. 2 through 4 are cross-sectional views showing a process of fabricating a metal interconnection of a semiconductor device according to an embodiment.

Referring to FIG. 2, a diffusion barrier 12, a first interlayer dielectric layer 14 and an etch stop layer 16 can be formed on a substrate 10.

The etch stop layer 16 and the first interlayer dielectric layer 14 can be selectively etched to form a first via V1. Here, the first interlayer dielectric layer 14 is not completely removed, but at least a predetermined thickness thereof remains, such that the diffusion barrier 12 is not exposed.

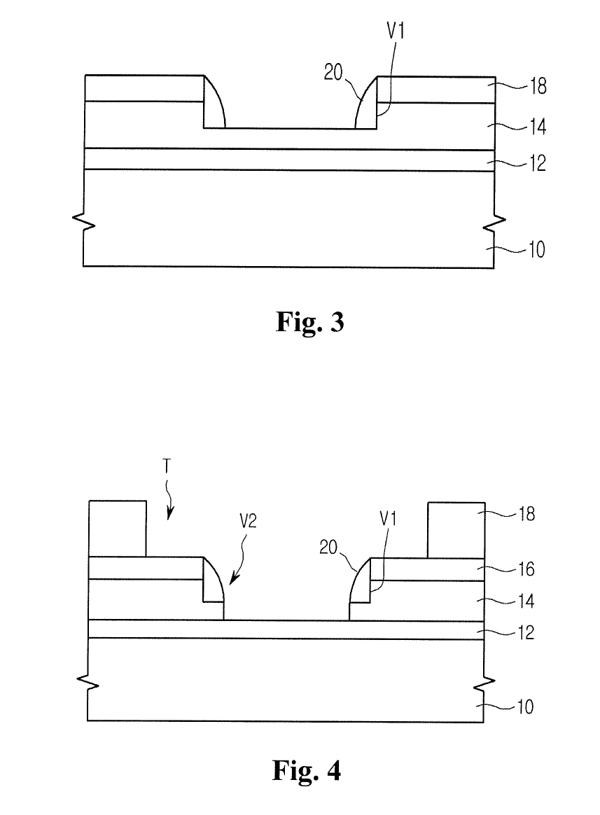

Referring to FIG. 3, a spacer 20 can be formed at sidewalls of the first via V1. The spacer 20 can be formed by forming a nitride layer on the substrate 10 including the first via V1, and removing portions of the nitride layer through an etch back process.

Referring to FIG. 4, a second interlayer dielectric layer 18 can be formed on the spacer 20, the first interlayer dielectric layer 14 and the etch stop layer 16, such that the first via V1 including the spacer 20 is filled with the second interlayer dielectric layer 18.

Then, a second via V2 and a trench T exposing the second via V2 can be formed by selectively etching the second interlayer dielectric layer 18. At this time, the first interlayer dielectric layer 14 exposed through the second via V2 is also removed, so the diffusion barrier 12 is exposed through the second via V2.

Since the spacer 20 formed according to embodiments of the present invention is smoothly curved, the second interlayer dielectric layer 18 may have no voids. Accordingly, the time taken to remove the second interlayer dielectric layer 18 may be consistent about the substrate including the second via V2, so the overetching caused by a void can be inhibited from occurring.

Herein, the width of the second via V2 can be less than that of the first via V1 because the first via V1 includes the spacer 20.

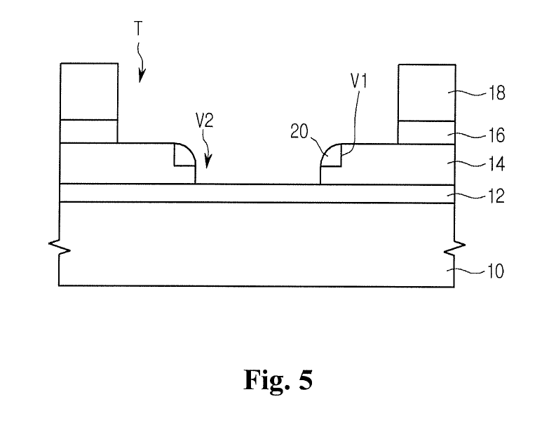

Referring to FIG. 5, the exposed etch stop layer 16 can be removed thereby completely forming the trench T. At this time, the exposed diffusion barrier 12 can also be removed to expose, for example, a lower interconnection.

Referring again to FIG. 1, a copper layer can be formed to fill the second via V2 and the trench T. In addition, a copper interconnection is formed by performing chemical mechanical polishing on the copper layer.

As described above, the spacer is formed at the corners of a first formed trench or via hole in order to improve the cohesive property of the top insulating layer, so voids can be inhibited from being formed in the insulating layer. Accordingly, the via for the metal interconnection and the trench can be formed without damaging a bottom layer, improving the reliability of the device.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other ones of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A method of fabricating a metal interconnection of a semiconductor device, comprising:
depositing a diffusion barrier, a first interlayer dielectric layer and an etch stop layer on a substrate;
forming a first via hole by removing portions of the etch stop layer and the first interlayer dielectric layer through a selective etching process, wherein a lower portion of the first interlayer dielectric layer remains below the first via hole;
forming spacers in the first via hole;
forming a second interlayer dielectric layer on the substrate and filling the first via hole having the spacers;
forming a second via hole exposing the diffusion barrier through the first via hole and a trench exposing the second via hole and a portion of the etch stop layer by removing portions of the second interlayer dielectric layer and the first interlayer dielectric layer through a selective etching process; and
removing the exposed etch stop layer.

2. The method according to claim 1, wherein forming the spacers comprises:
forming a nitride layer on the first interlayer dielectric layer including the first via hole and;
forming spacers along sidewalls of the first via hole by etching back the nitride layer.

3. The method according to claim 1, further comprising removing the exposed diffusion barrier.

4. The method according to claim 1, wherein the diffusion barrier comprises a nitride layer.

5. The method according to claim 1, wherein the etch stop layer comprises a nitride layer.

6. The method according to claim 1, wherein the first and second interlayer dielectric layers comprise at least one selected from the inorganic insulating material group consisting of FSG (fluorine silicate glass), USG (un-doped silicate glass), SiH₄ and TEOS (tetra ethyl ortho silicate).

7. The method according to claim 1, wherein at least one of the first and second interlayer dielectric layers comprises organic insulating material.

8. The method according to claim 1, wherein the first and second interlayer dielectric layers comprise at least one selected from the group consisting of BD (BLACK DIAMOND), silica xerogels, mesoporous silica, polyimide nanofoams, TEFLON-AF and TEFLON microemulsion.

9. The method according to claim 1, wherein the width of the second via hole is smaller than that of the first via hole.

10. The method according to claim 1, wherein removing the exposed etch stop layer removes a portion of the spacers.

11. The method according to claim 1, further comprising:
forming a copper layer on the substrate filling the second via and the trench; and
polishing the copper layer by performing a chemical mechanical polishing process.
